(19) United States
(12) Patent Application Publication
(10) Pub. No.: US 2024/0153979 A1
(43) Pub. Date: May 9, 2024

(54) Image Sensor Structure with Reduced Floating Node and Manufacturing Method Thereof

(71) Applicant: Taiwan Semiconductor Manufacturing Company, Ltd., Hsin-Chu (TW)

(72) Inventors: Wei Long CHEN, New Taipei City (TW); Wen-I HSU, Tainan City (TW); Feng-Chi HUNG, Hsin-Chu County (TW); Jen-Cheng LIU, Hsin-Chu City (TW); Dun-Nian YAUNG, Taipei City (TW)

(21) Appl. No.: 18/299,837

(22) Filed: Apr. 13, 2023

Related U.S. Application Data
(60) Provisional application No. 63/382,151, filed on Nov. 3, 2022.

(51) Int. Cl. H01L 27/146

(52) U.S. Cl. CPC H01L 27/1463; H01L 27/14603; H01L 27/14612; H01L 27/14683

(57) ABSTRACT

A method of manufacturing an image sensor structure includes forming an isolation structure in a substrate to divide the substrate into a first region and a second region, forming a first light sensing region in the first region and a second light sensing region in the second region, forming a first gate structure over the first light sensing region and a second gate structure over the second light sensing region, forming gate spacers on sidewalls of the first and second gate structures, and depositing a blocking layer on sidewalls of the gate spacers. The blocking layer has an opening positioned between the first and second gate structures. A source/drain structure is formed directly under the opening in the blocking layer. The method also includes forming an interlayer dielectric layer over the first and second gate structures and the blocking layer.

### PRIORITY DATA

This application claims the benefit of U.S. Provisional Application No. 63/382,151, filed Nov. 3, 2022, which is hereby incorporated by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Taking image-sensor device as an example, common image-sensor device defects include electron crosstalk, dark current, and white pixel. Electron crosstalk refers to electron interference from neighboring pixels that degrades the light-sensing reliability and accuracy of the pixels. Dark current may be defined as the existence of pixel current when no actual illumination is present. In other words, the dark current is the current that flows through the photodiode when no photons are entering the photodiode. White pixels occur where an excessive amount of current leakage causes an abnormally high signal from the pixels. The defects become more serious as the image pixel sizes and the spacing between neighboring image pixels continues to shrink. Therefore, although existing semiconductor manufacturing processes have generally been adequate for their intended purposes, as device scaling-down continues, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top-view representation of a pixel layout of an image sensor structure in accordance with some embodiments.

FIGS. 2A, 3A, 4A, 5A, 6A, 7A, 8A, 9A, 10A, 11A, 12A, 13A, 14A, 15A, and 16A are cross-sectional representations of various stages of forming the image sensor structure illustrated along line A-A shown in FIG. 1, in accordance with some embodiments.

FIGS. 2B, 3B, 4B, 5B, 6B, 7B, 8B, 9B, 10B, 11B, 12B, 13B, 14B, 15B, and 16B are cross-sectional representations of various stages of forming the image sensor structure illustrated along line B-B shown in FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Embodiments of an integrated circuit (IC) structure and methods for forming the same are provided. In some embodiments, the IC structure includes an image sensor. The image sensor includes an isolation structure isolating adjacent light sensing regions. Source/drain structures (in image sensor field, also called a floating node or floating diffusion well) are formed adjacent to the isolation structure. A contact is formed over the floating node. A blocking layer is formed prior to the formation of the floating node, so the size of the floating node is constrained within an opening defined in the blocking layer. The reduced size of the floating node expands the distance between the light sensing regions and the floating node, which in turn mitigates crosstalk, dark current, and white pixel from occurring.

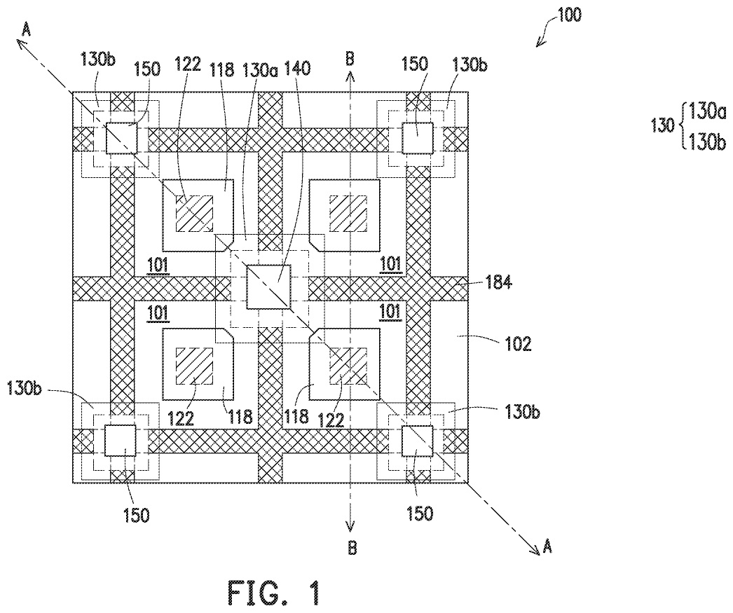

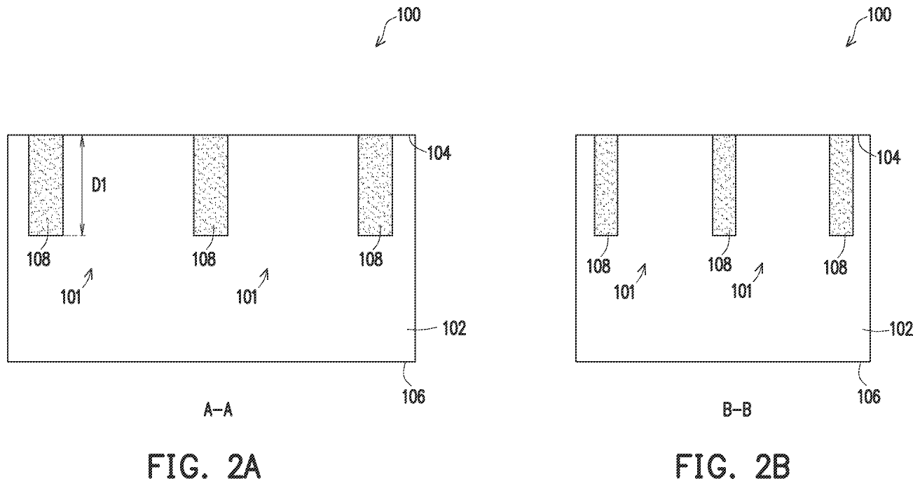

FIG. 1 illustrates a pixel layout of an image sensor structure 100 in accordance with some embodiments. FIGS. 2A to 16B are cross-sectional representations of various stages of forming the image sensor structure 100 as shown in FIG. 1 in accordance with some embodiments. The figures numbered with suffix “A” represent cross-sectional views along the A-A line as shown in FIG. 1. The figures numbered with suffix “B” represent cross-sectional views along the B-B line as shown in FIG. 1. It should be noted that image sensor structure 100 illustrated in FIGS. 1 to 16B has been simplified for the sake of clarity so that concepts of the present disclosure can be better understood. Therefore, in some other embodiments, additional features are added in image sensor structure 100, and some of the elements are replaced or eliminated.

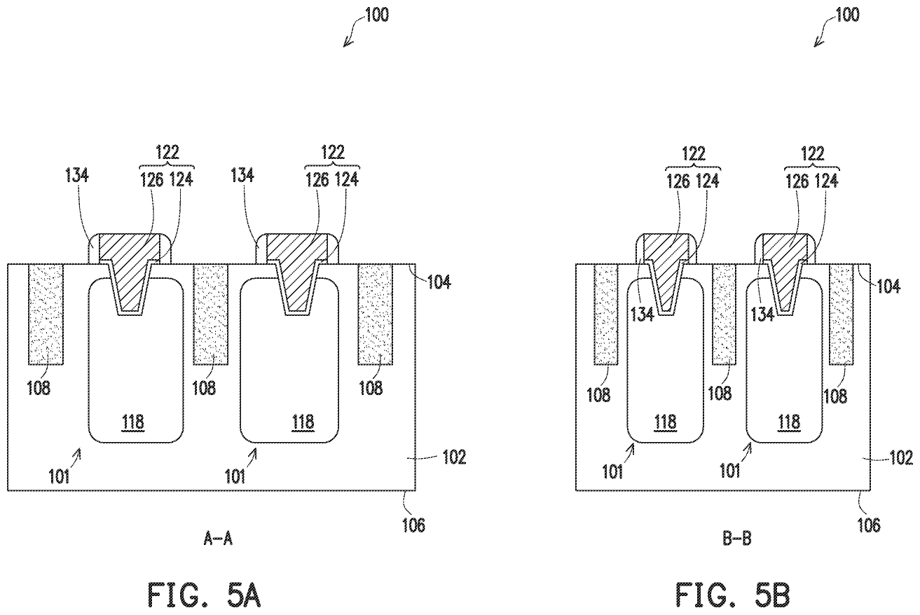

As depicted in FIG. 1, the image sensor structure 100 includes a grid of regions 101 containing light sensing regions 118 formed on or within a semiconductor substrate (or substrate) 102, in accordance with some embodiments. The regions 101 are also referred to as photodiodes or pixels, such as backside-illuminated pixels in the illustrated embodiment. Isolation structures, such as backside deep trench isolation (BDTI) structure 184 and/or frontside guard ring structure 108 (FIGS. 2A and 2B), are configured as multiple enclosures defining boundaries of the pixels 101. A source/drain structure 140 (also referred to as floating node or floating diffusion well) is disposed between adjacent pixels 101. In the illustrated embodiment, the source/drain structure 140 is shared by 2×2 pixels 101. Transfer gate structures 122 are formed over the light sensing regions 118. Gate spacers 134 (as shown in FIGS. 5A and 5B) are deposited on sidewalls of the gate structures 122. During the operation, the transfer gate structures 122 control charge transfer from the pixels 101 to the source/drain structure 140. If the charge level is sufficiently high within the source/drain structure 140, a source follower transistor (not shown) is activated and charges are selectively output according to operation of a row select transistor (not shown) used for addressing. A reset transistor (not shown) can be used to reset the pixels 101 between exposure periods.

Also depicted in FIG. 1 are blocking layers 130 disposed on sidewalls of the gate spacers 134. Each of the blocking layers 130 includes an opening in its center, which defines an implantation or diffusion area thereunder. Therefore, the blocking layers 130 are also referred to as masking elements. The blocking layers 130 include a first blocking layer 130a disposed in a center of the region of 2×2 pixels 101 and second blocking layers 130b disposed at corners of the region of 2×2 pixels 101. The opening in the first blocking layer 130a defines the implantation or diffusion area in forming the source/drain structure 140 thereunder. State differently, the first blocking layer 130a keeps the source/drain structure 140 in a distance away from sidewalls of the gate spacers 134. Without the blocking layer 130, the source/drain structure 140 may expand all the way to the gate spacers 134 and become too close to the light sensing regions 118. A source/drain structure 140 in close proximity to the light sensing regions 118 may easily pick up electrons from the light sensing regions 118 with a low threshold and cause issues including electron crosstalk, dark current, and white pixel in the image sensor structure 100. The openings in the second blocking layers 130b located at the corners define the implantation area in forming strapping wells 150. The strapping wells 150 are highly-doped regions providing bias to the substrate 102. In the depicted embodiment, each of the blocking layers 130 has a square shape in a top view, while other shapes (e.g., rectangular, circular, and irregular shapes) are also applicable. Further, in the depicted embodiment, the first blocking layer 130a overlaps with the four adjacent light sensing regions 118 in a top view and has a larger size and a larger opening size than the second blocking layers 130b which shrink at the corners and are distant from the light sensing regions 118 in a top view. Alternatively, each of the blocking layers 130 may have the same size and the same opening size.

Referring to FIGS. 2A and 2B, the substrate 102 is received, in accordance with some embodiments. In some embodiments, the substrate 102 is a semiconductor substrate including silicon. The substrate 102 may be a semiconductor wafer such as a silicon wafer. Alternatively or additionally, the substrate 102 may include elementary semiconductor materials, compound semiconductor materials, and/or alloy semiconductor materials. Examples of the elementary semiconductor materials may be, but are not limited to, crystal silicon, polycrystalline silicon, amorphous silicon, germanium, and/or diamond. Examples of the compound semiconductor materials may be, but are not limited to, silicon carbide, gallium arsenic, gallium phosphide, indium phosphide, indium arsenide, and/or indium antimonide. Examples of the alloy semiconductor materials may be, but are not limited to, SiGe, GaAsP, AlInAs, AlGaAs, GaInAs, GaInP, and/or GaInAsP. In at least one embodiment, the substrate 102 comprises p-type doped silicon.

The substrate 102 has a frontside surface 104 and a backside surface 106. A frontside implantation process is used to form a guard ring structure 108 implanted from the frontside surface 104. In at least one embodiment, the guard ring structure 108 is configured as multiple enclosures, e.g., squares (although other shapes are applicable), each square surrounding a pixel 101, which may, as disclosed herein, comprise multiple pixels. Since the guard ring structure 108 extends from the frontside surface 104 of the substrate 102 toward the backside surface 106 of the substrate 102, the guard ring structure 108 is also referred to as the frontside guard ring structure 108. As discussed in further detail below, backside deep trench isolation (BDTI) structure 184 (e.g., full BDTI and/or partial BDTI) is to be formed and in overlapping with the frontside guard ring structure 108 in a top view. Referring back to FIG. 1, the multiple enclosures of the BDTI structure 110, which surround the pixels 101, are depicted, while the frontside guard ring structure 108, which overlaps with the BDTI structure 110, is omitted in FIG. 1 for the sake of simplicity.

In some embodiments, the frontside guard ring structure 108 has a depth D1 ranging from about 50 nm to about 200 nm to provide efficient crosstalk isolation between the pixels 101. In at least one embodiment, high energy implantation, such as ion implantation or ion metal plasma implantation, is used on the frontside surface 104 of the substrate 102 to form the frontside guard ring structure 108. The materials implanted during the implantation include any one of boron, aluminum, and gallium as p-type dopants. Any combination of the above dopants may also be implanted. Typical ion implantation energies for the guard ring structure are in the range of between 400 keV and 2000 keV, and in some embodiments, in the narrower range of between 500 keV and 1500 keV. Therefore, the frontside guard ring structure 108 is p-type wells in accordance with some embodiments, and the depth D1 of the frontside guard ring structure 108 relies on the depth of dopant implantation. Once the frontside guard ring structure 108 is implanted, the substrate 102 is annealed to strengthen the substrate 102 and reduce brittleness. The annealing step anneals out most or all damage to the substrate caused by any ion implantation and/or activates any implanted dopant material. Annealing is performed using known annealing techniques including laser annealing, Rapid Thermal Annealing (RTA), laser annealing and conventional furnace annealing.

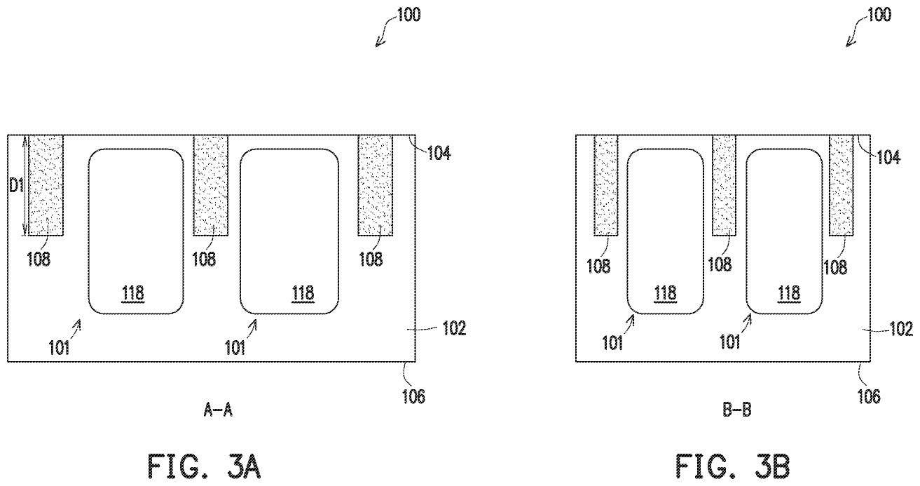

Referring to FIGS. 3A and 3B, after the frontside guard ring structure 108 is formed, the substrate 102 is divided by the frontside guard ring structure 108 into several regions to host the pixels 101, and a light sensing region 118 is formed in each of the regions, in accordance with some embodiments. The light sensing regions 118 are configured to sense (detect) incident light. The light sensing regions 118 may individually correspond to a range of wavelengths of red light, green light, or blue light. The light sensing regions 118 may be doped regions having n-type and/or p-type dopants formed in the substrate 102. The light sensing regions 118 may be formed by an ion implantation process, diffusion process, or other applicable processes. In some embodiments, the thickness of the light sensing regions 118 are greater than the depth D1 of the frontside guard ring structure 108. That is, the light sensing regions 118 are formed from the frontside surface 104 of the substrate 102, and the bottom surfaces of the light sensing regions 118 are lower than the bottom surface of frontside guard ring structure 108.

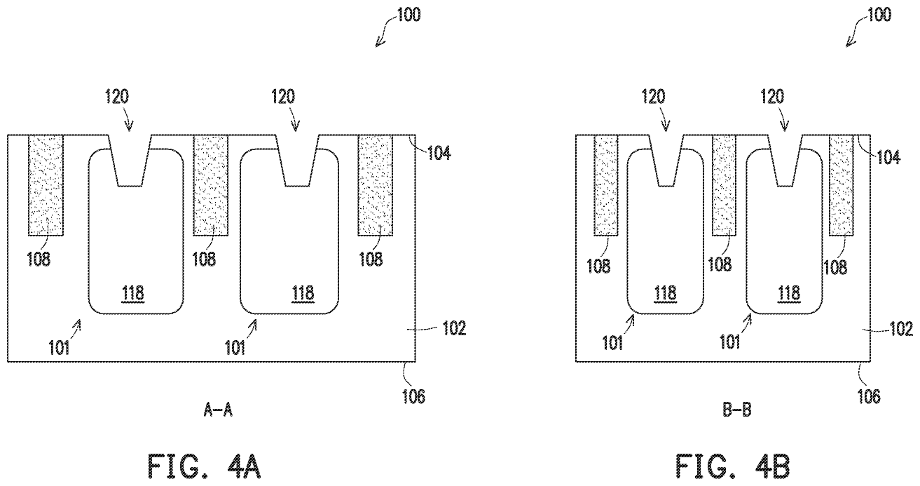

Referring to FIGS. 4A and 4B, openings 120 are formed in the frontside surface 104 of the substrate 102. The openings 120 are formed spaced apart. Particularly, one opening 120 is formed above one of the light sensing regions 118. The opening 120 may be formed extending below a top surface of the light sensing region 118. In some embodiments, the openings 120 are formed with angled sidewalls. In some embodiments, a process for forming the openings 120 includes a masking layer (not shown) on the frontside surface 104 of the substrate 102. Thereafter, the substrate 102 is exposed to an etchant to remove unmasked portions of the substrate 102, thereby forming the openings 120. Subsequently, in some embodiments, the masking layer is stripped away.

Referring to FIGS. 5A and 5B, gate structures 122 are formed over the frontside surface 104 of the substrate 102 and in the openings 120, in accordance with some embodiments. The gate structure 122 may be formed by forming a gate dielectric layer and a conductive layer over the frontside surface 104 of the substrate 102 and in the openings 120 and patterning the gate dielectric layer and the conductive layer. The openings 120 allow the gate structures 122 to protrude into the light sensing regions 118 and increase the gate control performance. In some embodiments, the gate structures 122 include a gate dielectric layer 124 and a gate electrode layer 126. Gate spacers 134 are formed on the sidewalls of gate structures 122.

The gate dielectric layer 124 is formed on the frontside surface 104 of the substrate 102 and lining the openings 120. In some embodiments, the gate dielectric layer 124 may be deposited or grown by, for example, chemical vapor deposition (CVD), physical vapor deposition (PVD), atomic layer deposition (ALD), thermal oxidation, sputtering, some other deposition or growth process, or a combination thereof. In some embodiments, the gate dielectric layer 124 is made of oxide. In some embodiments, the gate dielectric layer 124 are made of high-k dielectric material, such as metal oxide, metal nitride, metal silicate, transition metal-oxide, transition metal-nitride, transition metal-silicate, or oxynitride of metals. Examples of the high-k dielectric material include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials.

The gate electrode layer 126 is formed on the gate dielectric layer 124. In some embodiments, the gate electrode layer 126 may be deposited by, for example, CVD, PVD, ALD, sputtering, electrochemical plating, electroless plating, some other deposition process, or a combination thereof. In some embodiments, the gate electrode layer 126 is made of polysilicon. In some embodiments, the gate electrode layer 126 is made of conductive materials, such as aluminum, copper, tungsten, titanium, tantalum, or other applicable materials.

The gate spacers 134 are formed on the sidewalls of the gate structure 122. The gate spacers 134 may be formed by forming a dielectric layer over the frontside surface 104 of the substrate 102 to cover sidewalls and top surfaces of the gate structures 122 and anisotropically etching the dielectric layer to remove horizontal portions from the frontside surface 104 and the top surfaces of the gate structures 122. The vertical portions of the dielectric layer remain on the sidewalls of the gate structures 122 as the gate spacers 134. In some embodiments, the gate spacers 134 are made of silicon nitride, silicon oxide, silicon oxynitride, silicon oxycarbide (SiOC), silicon oxycarbon nitride (SiOCN), silicon carbide, or other applicable dielectric materials.

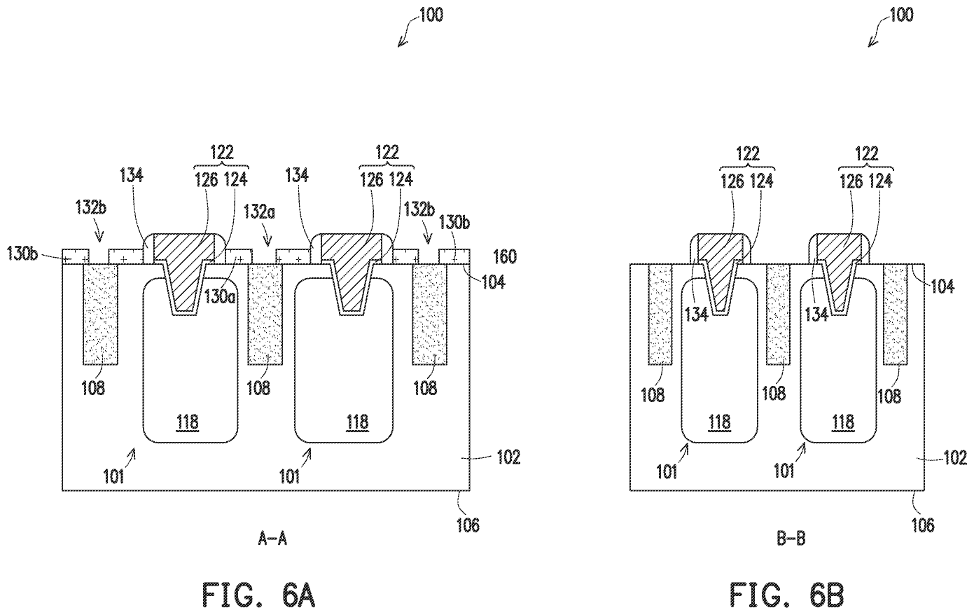

Referring to FIGS. 6A and 6B, blocking layers 130 are formed over the frontside surface 104 of the substrate 102. The blocking layers 130 provide openings 132 over the frontside guard ring structure 108. As discussed above with reference to FIG. 1, the blocking layers 130 may include a first blocking layer 130a with a first opening 132a disposed in a center of the region of 2×2 pixels 101 and four second blocking layers 130b with second openings 132b disposed at four corners of the region of 2×2 pixels 101. The frontside guard ring structure 108 is exposed in the openings 132 while other portions of the frontside surface 104 extending from the sidewalls of the gate spacers 134 to the openings 132 are covered by the blocking layers 130. In the depicted embodiment, the openings 132 are smaller than a width of the frontside guard ring structure 108, such that the frontside guard ring structure is partially exposed in the openings 132 (as in FIG. 6A) and the blocking layers 130 extends continuously from the sidewalls of the gate spacers 134 to a position directly above the frontside guard ring structure 108. Alternatively, the openings 132 may be larger than a width of the frontside guard ring structure 108, such that the frontside guard ring structure 108 and a portion of the frontside surface 104 of the substrate 102 adjacent to the frontside guard ring structure 108 are exposed in the openings 132.

The blocking layers 130 includes a material that is different than a material of the gate spacer 134, in some embodiments. For example, the blocking layers 130 include a dielectric material such as a hard mask layer comprising silicon nitride or silicon oxide. In some embodiments, the blocking layers 130 include a multi-layer structure with different dielectric materials, such as a bottom layer of silicon oxide and a top layer of silicon nitride. The present disclosure contemplates other materials for the blocking layers 130, such as metal oxides (e.g., aluminum oxide). In the depicted embodiment, the blocking layers 130 have a thickness less than a thickness of the gate structures 122, such that a top surface of the blocking layers 130 is below a top surface of the gate structures 122 and the gate spacers 134. Alternatively, the thickness of the blocking layer 130 and the gate spacers 134 may be the same, and the top surfaces of the blocking layers 130 and the gate structures 122 may be level with each other.

In some embodiments, the blocking layers 130 are patterned to form the openings 132, such as by a lithography process that includes forming a resist layer (not shown) over the blocking layers 130 (e.g., by spin coating), performing a pre-exposure baking process, performing an exposure process using a mask, performing a post-exposure baking process, and performing a developing process. During the exposure process, the resist layer is exposed to radiation energy (e.g., UV light, DUV light, or EUV light), where the mask blocks, transmits, and/or reflects radiation to the resist layer depending on a mask pattern of the mask and/or mask type (e.g., binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the openings 132. Alternatively, the exposure process can be implemented or replaced by other methods, such as maskless lithography, e-beam writing, ion-beam writing, or combinations thereof. Subsequently, an etching process is performed to transfer the resist pattern to the blocking layers 130 and the patterned resist layer is stripped away thereafter.

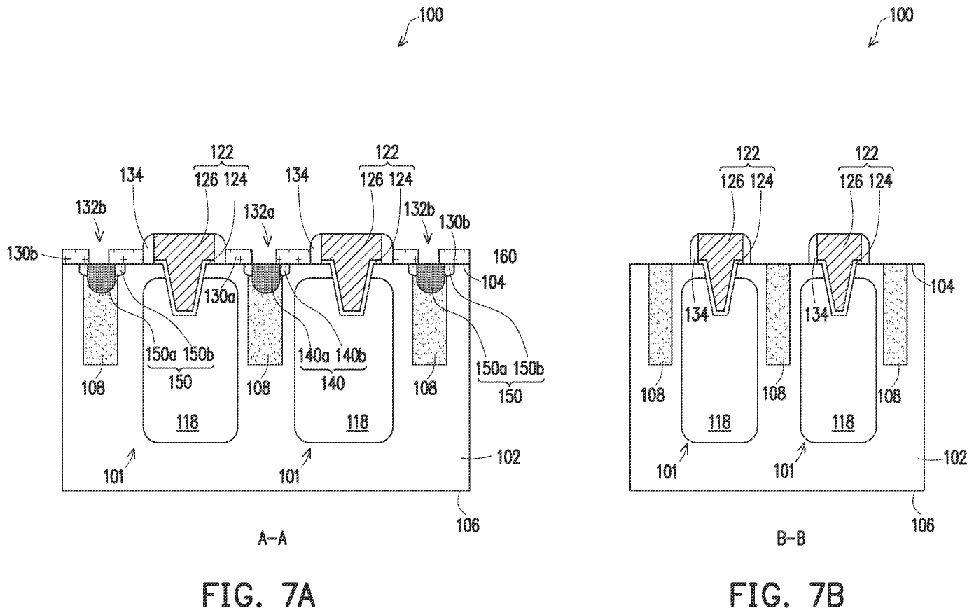

Referring to FIGS. 7A and 7B, a source/drain structure 140 is formed by implanting n-type dopants into the substrate 102 through the first opening 132a, and strapping wells 150 are formed by implanting p-type dopants into the substrate 102 through the second openings 132b. The materials implanted during the implantation include any one of boron, aluminum, gallium, and a combination thereof as p-type dopants and any one of antimony, phosphorus, arsenic, and a combination thereof as n-type dopants. The implantation of the n-type and p-type dopants may be performed in two separate implantation processes in sequence. In the depicted embodiment, the dopants are also doped in the upper portion of the frontside guard ring structure 108. Alternatively, the source/drain structure 140 may be formed by recessing the frontside surface 104 of the substrate 102 to form a recess and epitaxially growing strained materials in the recess. In the depicted embodiment, the top surface of the source/drain structure 140, the top surface of the frontside guard ring structure 108, the frontside surface 104 of the substrate 102 are substantially level with one another. The bottom surfaces of the source/drain structure 140 and the strapping wells 150 are above the bottom surface of the protruding portion of the gate structure 122.

In some embodiments, the frontside guard ring structure 108 is p-type doped. During the implantation process, the top portion of the frontside guard ring structure 108 exposed in the opening 132a receives n-type dopant, and the polarity of the top portion of the frontside guard ring structure 108 is eventually flipped when the n-type dopant concentration exceeds the original p-type dopant concentration. The implantation process may continue until the net n-type dopant concentration is significantly higher than the original p-type dopant concentration in the top portion of the frontside guard ring structure 108. Although the implantation is limited in the first opening 132a, diffusion of the n-type dopant may result in a center highly-doped n-type region 140a and a peripheral lightly-doped n-type region 140b. The n-type dopant concentration in the peripheral lightly-doped n-type region 140b may be lower than the p-type dopant concentration in the frontside guard ring structure 108. The peripheral lightly-doped n-type region 140b extends under the first blocking layer 130a. Nonetheless, in various embodiments, the peripheral lightly-doped n-type region 140b may still be offset from the sidewalls of the gate spacers 134. Similarly, the strapping wells 150 may include a center highly-doped p-type region 150a and a peripheral lightly-doped p-type region 150b. The p-type dopant concentration in the peripheral lightly-doped p-type region 150b may be lower than the p-type dopant concentration in the lower portion of the frontside guard ring structure 108. In the depicted embodiment, the openings 132 are smaller than a width of the frontside guard ring structure 108, and the center highly-doped n-type region 140a and the center highly-doped p-type region 150a may be narrower than the width of the frontside guard ring structure 108 and stay within sidewalls of the frontside guard ring structure 108, yet the peripheral lightly-doped n-type region 140b and the peripheral lightly-doped p-type region 150b extend beyond sidewalls of the frontside guard ring structure 108.

The sizes of the source/drain structure 140 and the strapping wells 150 are relatively small due to the formation of the blocking layers 130. Therefore, there can be a greater spacing between the light sensing regions 118 and the source/drain structure 140 and the strapping wells 150. Image-sensor device defects including electron crosstalk, dark current, and white pixel are suppressed, and quantum efficiency of the resulting image sensor structure 100 can be improved.

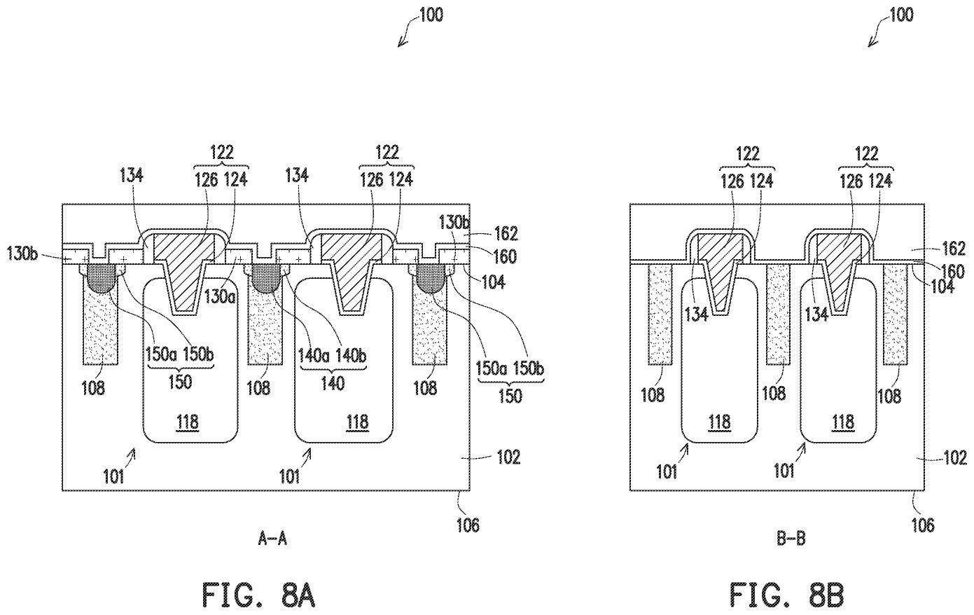

Referring to FIGS. 8A and 8B, after the source/drain structure 140 and the strapping wells 150 are formed, an inter-layer dielectric (ILD) layer 162 is formed over the frontside surface 104 of the substrate 202. In some embodiments, a contact etch stop layer (CESL) 160 is formed over the frontside surface 104 of the substrate 102 prior to forming the ILD layer 162. In some examples, the CESL 160 includes a silicon nitride layer, silicon oxide layer, a silicon oxynitride layer, and/or other materials known in the art. In furtherance of embodiment, the gate spacers 134, the blocking layer 130, and the CESL 160 may include different material compositions from each other. The CESL 160 may be formed by plasma-enhanced chemical vapor deposition (PECVD) process and/or other suitable deposition or oxidation processes. In some embodiments, the ILD layer 162 includes materials such as tetraethylorthosilicate (TEOS) oxide, un-doped silicate glass, or doped silicon oxide such as borophosphosilicate glass (BPSG), FSG, phosphosilicate glass (PSG), boron doped silicon glass (BSG), and/or other suitable dielectric materials. The ILD layer 162 may be deposited by a PECVD process or other suitable deposition technique. In some embodiments, after depositing the ILD layer 162, a planarization process, such as a chemical mechanical polishing (CMP) process, may be performed to remove excess material and planarize a top surface of the image sensor structure 100.

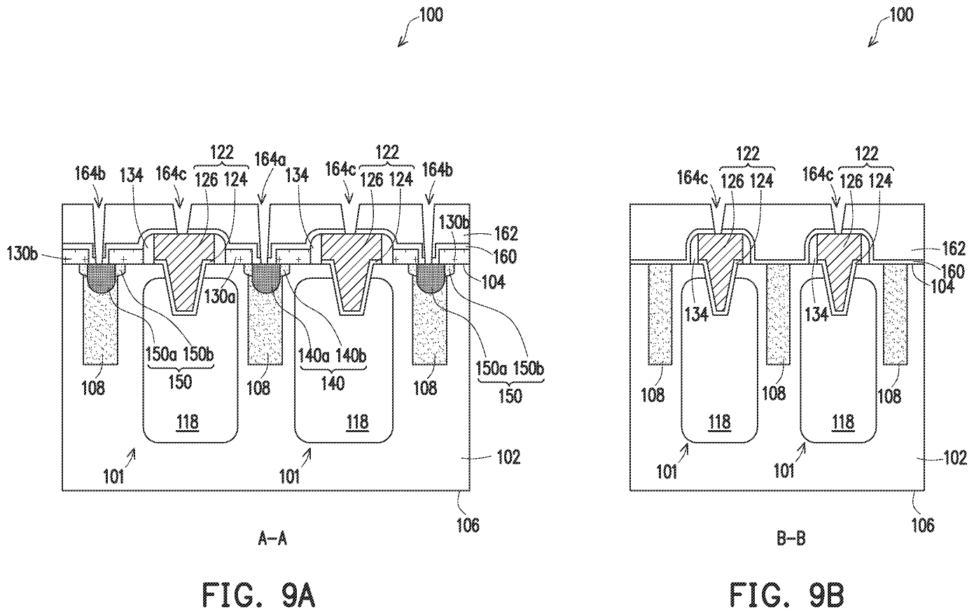

Referring to FIGS. 9A and 9B, contact trenches 164, including a first contact trench 164a, second contact trenches 164b, and third contact trenches 164c, are formed through the ILD layer 162, in accordance with some embodiments. The first contact trench 164a is formed over the source/drain structure 140, the second contact trenches 164b are formed over the strapping wells 150, and the third contact trenches 164c are formed over the gate structures 122. The formation of the contact trenches 164 may include, for example but is not limited to: forming a patterned hard mask (not shown) with openings defined above the source/drain structure 140, the strapping wells 150, and the gate structures 122; performing one or more etching processes to form contact trenches extending through the ILD layer 162 and the CESL 160 to expose the features thereunder. The contact trenches 164 may be etched using a dry etch (e.g., reactive ion etching), a wet etch, or a combination thereof.

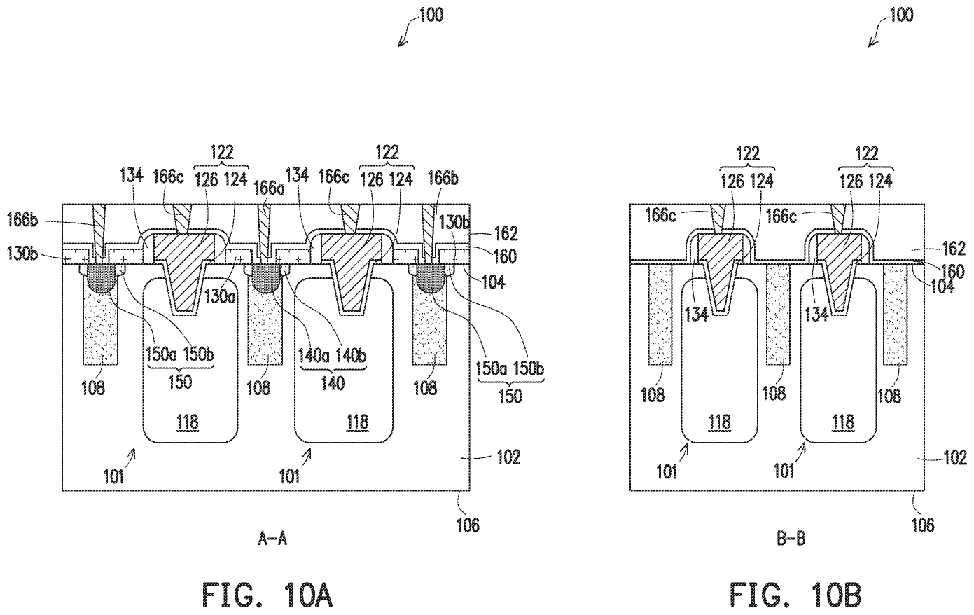

Referring to FIGS. 10A and 10B, contacts 166, including a floating node contact 166a, strapping well contacts 166b, and gate contacts 166c, are formed in the first contact trench 164a, the second contact trenches 164b, and the third contact trenches 164c, respectively. The floating node contact 166a is electrically contacted with the source/drain structure 140, the strapping well contact 166b are electrically contacted with the strapping wells 150, and the gate contacts 166c are electrically contacted with the gate structures 122.

The contacts 166 may be formed by filling the contact trenches 164 by a conductive material. In some embodiments, the conductive material includes aluminum (Al), copper (Cu), tungsten (W), titanium (Ti), tantulum (Ta), titanium nitride (TiN), tantalum nitride (TaN), nickel silicide (NiS), cobalt silicide (CoSi), tantulum carbide (TaC), tantulum silicide nitride (TaSiN), tantalum carbide nitride (TaCN), titanium aluminide (TiAl), titanium aluminide nitride (TiAlN), other applicable conductive materials, or a combination thereof. In addition, the contacts 166 may further include a liner and/or a barrier layer. For example, a liner (not shown) may be formed on the sidewalls and bottom of the contact trenches 164. The liner may be silicon nitride, although any other applicable dielectric may alternatively be used. The liner may be formed using a plasma enhanced chemical vapor deposition (PECVD) process, although other applicable processes, such as physical vapor deposition or a thermal process, may alternatively be used. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

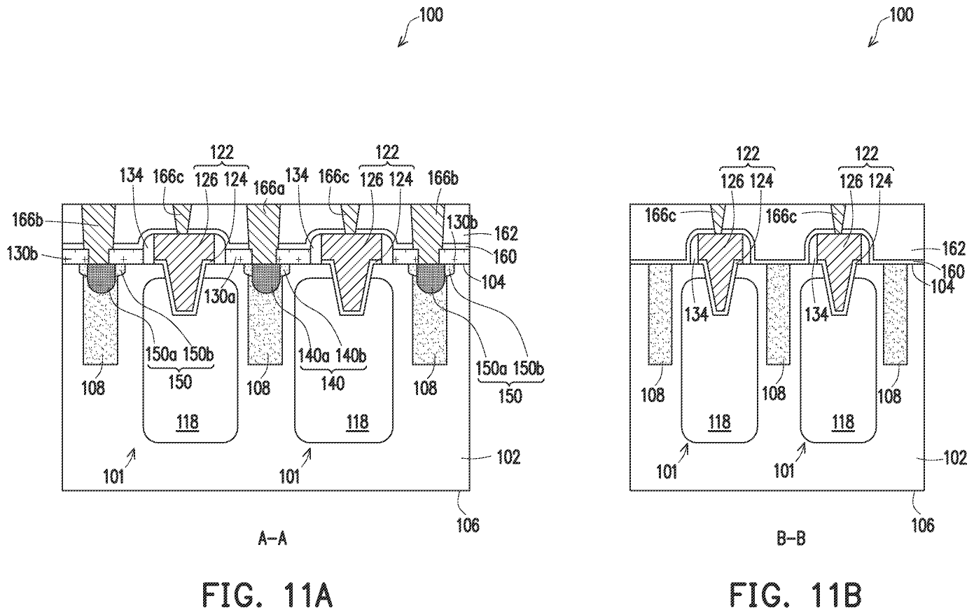

Referring to FIGS. 11A and 11B, in an alternative embodiment, the contacts 166a and 166b may be formed self-aligned. As the openings 132a and 132b are already defined in the blocking layers 130a and 130b and above the source/drain structure 140 and the strapping wells 150, respectively, the contact trenches 164a and 164b may be formed in a manner larger than the openings 132a and 132b, providing a larger process window. Due to the etching selectivity, the ILD layer 162 and the CESL 160 filling the openings 132a and 132b are removed, exposing sidewalls of the blocking layers 130a and 130b in the contact trenches 164a and 164b, respectively. Subsequently, contacts 166a and 166b are formed by filling the contact trenches 164a and 164b by a conductive material, as discussed above. The bottom portion of the contact trenches 164a and 164b are in direct contact with the sidewalls of the blocking layers 130a and 130b, respectively. The widths of the contacts 166a and 166b may be larger than the width of the gate contacts 166c. Also, since the opening 132a may be wider than the openings 132b, the bottom portion of the floating node contact 166a may be larger than the bottom portion of the strapping well contacts 166b. In the following figures, the manufacturing operations after the structure shown in FIGS. 10A and 10B is formed are explained. However, the same operations can be applied to the structure shown in FIGS. 11A and 11B.

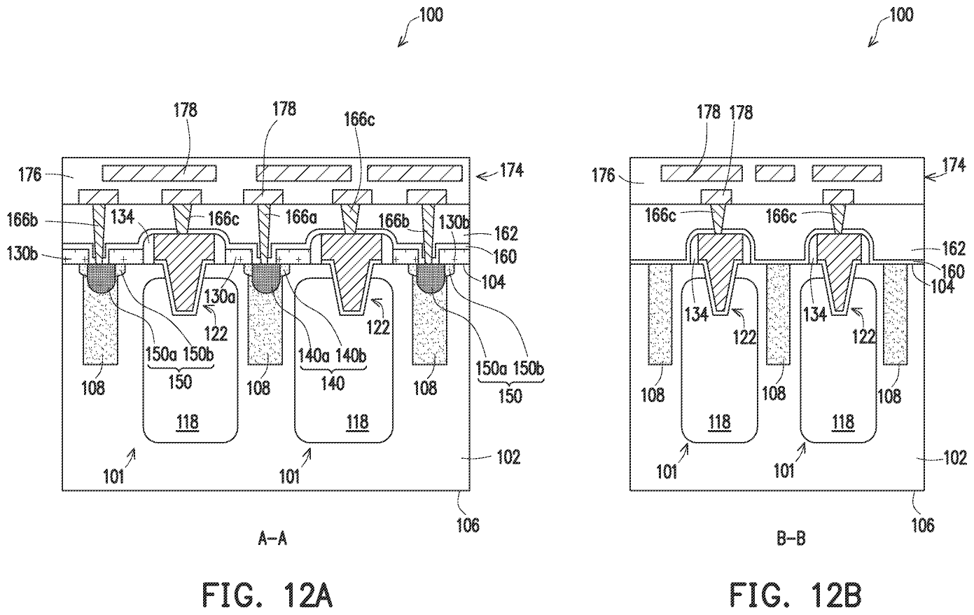

Referring to FIGS. 12A and 12B, an interconnect structure 174 is formed over the ILD layer 162, in accordance with some embodiments. That is, the interconnect structure 174 is formed over the frontside surface 104 of the substrate 102. In some embodiments, the interconnect structure 174 includes a dielectric layer 176 and conductive features 178 formed in the dielectric layer 176. In some embodiments, the dielectric layer 176 is an inter-metal dielectric (IMD) layer. In some embodiments, the dielectric layer 176 includes multilayers made of multiple dielectric materials, such as silicon oxide, silicon nitride, silicon oxynitride, phosphosilicate glass (PSG), borophosphosilicate glass (BPSG), or other applicable low-k dielectric materials. The dielectric layer 176 may be formed by a chemical vapor deposition (CVD), physical vapor deposition, (PVD), atomic layer deposition (ALD), spin-on coating, or other applicable processes. The conductive features 178 may be configured to connect various features or structures of image sensor structure 100. For example, the conductive features 178 are used to interconnect the floating node contact 166a, the strapping well contacts 166b, and the gate contacts 166c formed over the substrate 102. The conductive features 178 may be vertical interconnects, such as vias and contacts, and/or horizontal interconnects, such as conductive lines. In some embodiments, the conductive features 178 are made of conductive materials, such as aluminum, aluminum alloy, copper, copper alloy, titanium, titanium nitride, tungsten, polysilicon, or metal silicide. It should be noted that the conductive features 178 as illustrated are merely examples for better understanding the concept of the disclosure, and the scope of disclosure is not intended to be limiting. That is, the conductive features 178 may be arranged in various ways in various embodiments.

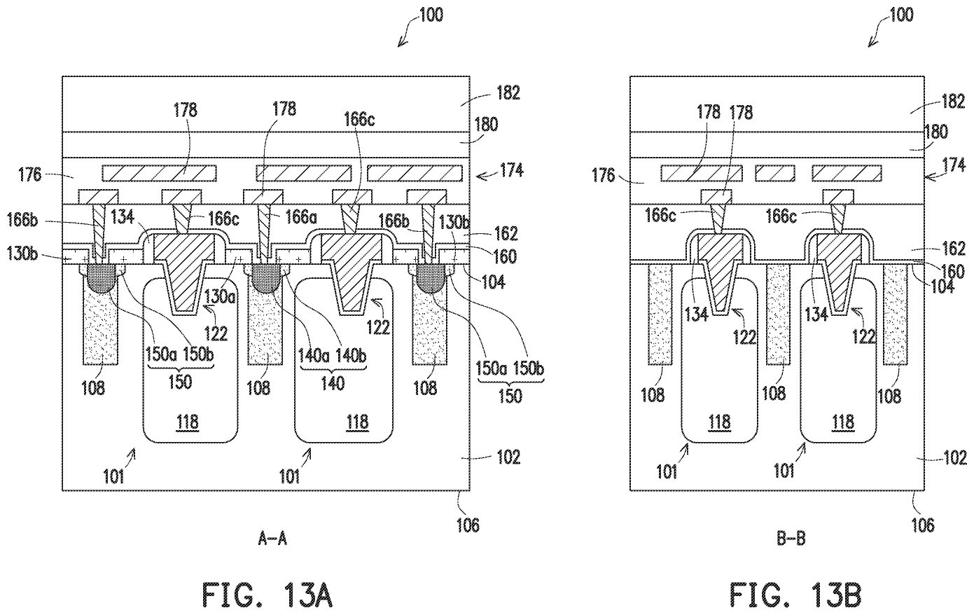

Referring to FIGS. 13A and 13B, a buffer layer 180 is formed over interconnect structure 174, in accordance with some embodiments. In some embodiments, the buffer layer 180 is made of silicon oxide, silicon nitride, or other applicable dielectric materials. The buffer layer 180 may be formed by CVD, PVD, or other applicable techniques. In some embodiments, the buffer layer 180 is planarized to form a smooth surface by a chemical-mechanical-polishing (CMP) process. Next, a carrier substrate 182 is bonded with the buffer layer 180. The carrier substrate 182 is configured to provide mechanical strength and support for processing the backside surface 106 of the substrate 102 in subsequent processes. The carrier substrate 182 may be similar to the substrate 102 or may be a glass substrate.

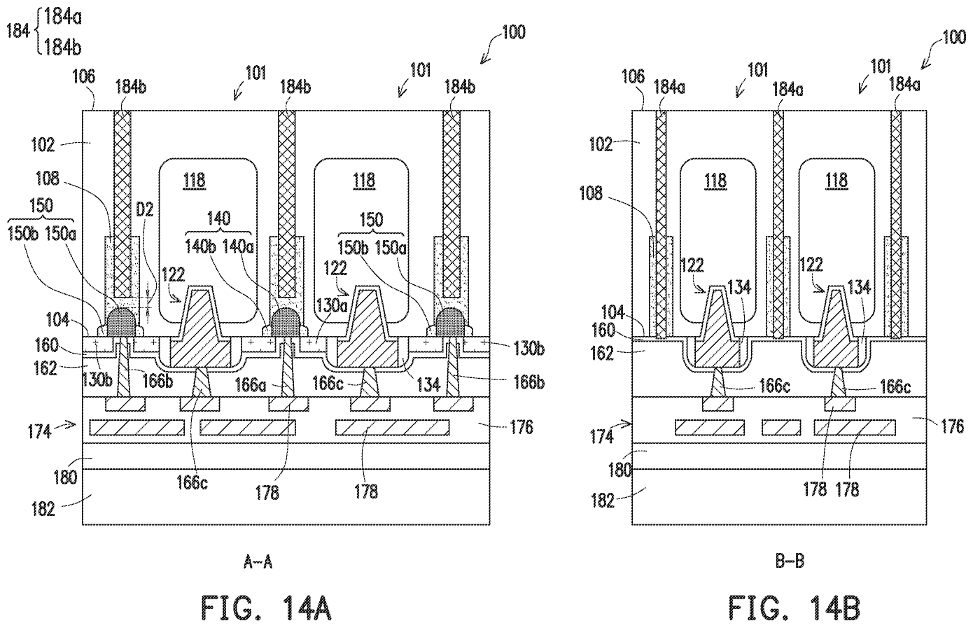

Referring to FIGS. 14A and 14B, the image sensor structure 100 is flipped and BDTI structure 184 is formed from the backside surface 106 of the substrate 102. In the depicted embodiment, the BDTI structure 184 includes full BDTI structure 184a and partial BDTI structure 184b. The full BDTI structure 184a fully isolate the pixel region from adjacent pixel regions. The full BDTI structure 184a extends from the backside surface 106 of the substrate 102 to the frontside surface 104 of the substrate 102. In some embodiments, the full BDTI structure 184a extends past the frontside surface 104 of the substrate 102 and into the CESL 160. In the depicted embodiment, a width of the frontside guard ring structure 108 is larger than a width of the BDTI structure 184. As the full BDTI structure 184a extends through the substrate 102, it also extends through the frontside guard ring structure 108. The partial BDTI structure 184b is disposed directly under the source/drain structure 140 and the strapping wells 150. The partial BDTI structure 184b has a height less than the full BDTI structure 184a. The partial BDTI structure 184b extends partially through the frontside guard ring structure 108 and spaced apart from the bottom surfaces of the source/drain structure 140 and the strapping wells 150 for a distance D2 ranging from about 10 nm to about 100 nm in some embodiments. In some embodiments, the full BDTI structure 184a and the partial BDTI structure 184b comprise the same fill material. The fill material provides electrical and optical isolation between shared pixel regions and may be a dielectric such as silicon dioxide, silicon nitride, silicon carbide, or the like.

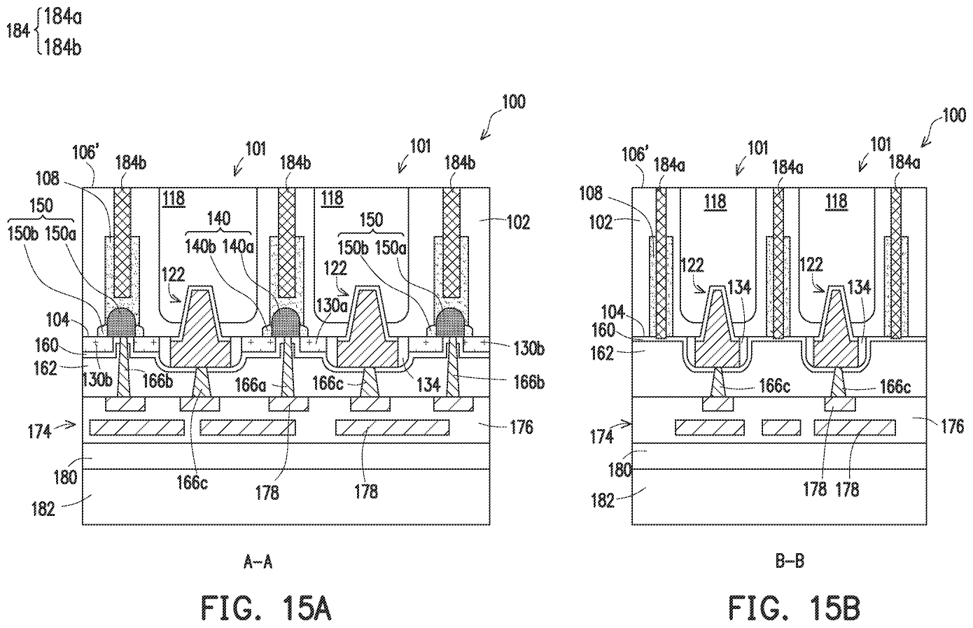

Referring to FIGS. 15A and 15B, the backside surface 106 of the substrate 102 is polished to expose the light sensing regions 118, in accordance with some embodiments. Accordingly, a thinned substrate 102 having a backside surface 106′ is formed. The light sensing regions 118 are exposed from the backside surface 106′ of the thinned substrate 102. In some embodiments, the substrate 102 is polished by a chemical mechanical polishing (CMP) process. In some embodiments, a portion of the BDTI structure 184 is removed during the polishing process. In various embodiments, the backside surfaces of the full BDTI structure 184a, the partial BDTI structure 184b, the light sensing regions 118 are substantially co-planar with one another.

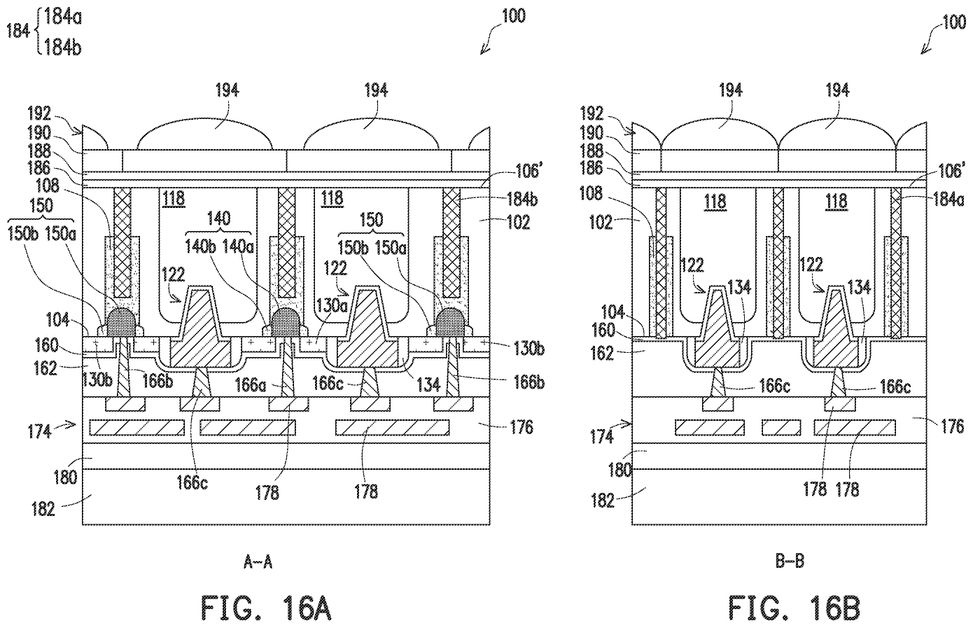

Referring to FIGS. 16A and 16B, an antireflective layer 186 is formed over backside surface 106′ of the thinned substrate 102, such that exposed light sensing regions 118 are covered by the antireflective layer 186, in accordance with some embodiments. In some embodiments, antireflective layer 186 is made of silicon carbide nitride, silicon oxide, or the like. After the antireflective layer 186 is formed, a passivation layer 188 is formed over the antireflective layer 186. In some embodiments, the passivation layer 188 is made of silicon nitride or silicon oxynitride. After the passivation layer 188 is formed, a color filter layer 190 is formed over the passivation layer 188, and a microlens layer 192 is disposed over the color filter layer 190. The color filter layer 190 may include multiple color filters. In some embodiments, each color filter is respectively aligned with the light sensing region 118. In some embodiments, the color filters are made of a dye-based (or pigment-based) polymer for filtering out a specific frequency band of radiation. In some embodiments, the color filters are made of resin or other organic-based material having color pigments. In some embodiments, the microlens layer 192 includes multiple microlens 194. In some embodiments, each microlen 194 is respectively aligned with the color filter and therefore respectively aligned with the light sensing region. However, it should be noted that microlens layer 192 may be arranged in various positions in various applications.

Referring back to FIG. 1, since the size of the source/drain structure 140 may be reduced, the distance between the surrounding light sensing regions 118 and the source/drain structure 140 may be enlarged, which reduces the defects of electron crosstalk, dark current, and white pixel. Since the size of the strapping wells 150, which provide bias for the substrate 102, may be reduced as well, the distance between the strapping wells 150 and the light sensing regions 118 may also be enlarged. Overall, the quantum efficiency may be increased, and the performance of image sensor structure 100 may be improved. Embodiments of the present disclosure can be readily integrated into existing semiconductor manufacturing processes.

In one exemplary aspect, the present disclosure is directed to a method for manufacturing an image sensor structure. The method includes forming an isolation structure in a substrate to divide the substrate into a first region and a second region, forming a first light sensing region in the first region and a second light sensing region in the second region, forming a first gate structure over the first light sensing region and a second gate structure over the second light sensing region, the first gate structure and the second gate structure being positioned at a frontside surface of the substrate, forming gate spacers on sidewalls of the first and second gate structures, depositing a blocking layer on sidewalls of the gate spacers, the blocking layer having an opening positioned between the first and second gate structures, forming a source/drain structure directly under the opening in the blocking layer, and forming an interlayer dielectric layer over the first and second gate structures and the blocking layer. In some embodiments, the method further includes forming a contact trench through the interlayer dielectric layer, such that a portion of the source/drain structure is exposed by the contact trench, and forming a contact in the contact trench. In some embodiments, the opening is directly above the isolation structure. In some embodiments, the forming of the isolation structure includes implanting a first type dopant into a top portion of the substrate, the forming of the source/drain structure includes implanting a second type dopant into a top portion of the isolation structure, and the first type dopant and the second type dopant have opposite conductivities. In some embodiments, the first type dopant is a p-type dopant, and the second type dopant is an n-type dopant. In some embodiments, the gate spacers and the blocking layer include different material compositions. In some embodiments, the blocking layer being a first blocking layer and the opening is a first opening, the method further includes depositing a second blocking layer, the first gate structure being positioned between the first and second blocking layers, and the second blocking layer having a second opening, and forming a strapping well directly under the second opening in the second blocking layer. In some embodiments, the strapping well and the source/drain structure include dopants of opposite conductivities. In some embodiments, the forming of the first and second gate structures includes etching the frontside surface of the substrate to form a first recess and a second recess, the first recess exposing the first light sensing region, and the second recess exposes the second light sensing region, depositing a gate dielectric layer and a gate electrode layer in the first recess and the second recess, and patterning the gate dielectric layer and the gate electrode layer to form the first and second gate structures. In some embodiments, a bottom surface of the source/drain structure is above bottom surfaces of the first and second gate structures.

In another exemplary aspect, the present disclosure is directed to a method for manufacturing an image sensor structure. The method includes forming an isolation structure in a substrate to define an enclosure, forming a light sensing region in the enclosure, forming a gate structure above the light sensing region, depositing a first gate spacer on a first sidewall of the gate structure, depositing a second gate spacer on a second sidewall of the gate structure, the second sidewall being opposing the first sidewall, depositing a first blocking layer on the first gate spacer, the first blocking layer including a first opening, depositing a second blocking layer on the second gate spacer, the second blocking layer including a second opening, implanting a first dopant into the substrate through the first opening to form a first doped region, and implanting a second dopant into the substrate through the second opening to form a second doped region, the first and second dopants including opposite conductivities. In some embodiments, the method further includes depositing a dielectric layer covering the first and second blocking layers, the first and second gate spacers, and the first and second gate structures, forming a first contact through the dielectric layer and in physical contact with the first doped region, and forming a second contact through the dielectric layer and in physical contact with the second doped region. In some embodiments, the first contact is in physical contact with sidewalls of the first opening, and the second contact is in physical contact with sidewalls of the second opening. In some embodiments, the first dopant is an n-type dopant, and the second dopant is a p-type dopant. In some embodiments, a size of the first doped region is larger than a size of the second doped region in a top view of the image sensor structure. In some embodiments, each of the first and second blocking layers has a square shape or a rectangular shape in a top view of the image sensor structure. In some embodiments, each of the first and second openings is directly above the isolation structure.

In another exemplary aspect, the present disclosure is directed to an image sensor structure. The image sensor structure includes an isolation structure in a substate, first and second light sensing regions at opposite sides of the isolation structure, first and second gate structures above the first and second light sensing regions, respectively, gate spacers on sidewalls of the first and second gate structures, a blocking layer on sidewalls of the gate spacers, the blocking layer having a discontinuity directly above at least a portion of the isolation structure, and a source/drain structure disposed above the portion of the isolation structure. In some embodiments, the source/drain structure is located directly under the discontinuity of the blocking layer. In some embodiments, a first portion of the blocking layer is directly above the first light sensing region, and a second portion of the blocking layer is directly above the second light sensing region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an image sensor structure, comprising:
forming an isolation structure in a substrate to divide the substrate into a first region and a second region;
forming a first light sensing region in the first region and a second light sensing region in the second region;
forming a first gate structure over the first light sensing region and a second gate structure over the second light sensing region, wherein the first gate structure and the second gate structure are positioned at a frontside surface of the substrate;
forming gate spacers on sidewalls of the first and second gate structures;
depositing a blocking layer on sidewalls of the gate spacers, the blocking layer having an opening positioned between the first and second gate structures;
forming a source/drain structure directly under the opening in the blocking layer; and
forming an interlayer dielectric layer over the first and second gate structures and the blocking layer.

2. The method of claim 1, further comprising:
forming a contact trench through the interlayer dielectric layer, such that a portion of the source/drain structure is exposed by the contact trench; and
forming a contact in the contact trench.

3. The method of claim 1, wherein the opening is directly above the isolation structure.

4. The method of claim 1, wherein the forming of the isolation structure includes implanting a first type dopant into a top portion of the substrate, the forming of the source/drain structure includes implanting a second type dopant into a top portion of the isolation structure, and the first type dopant and the second type dopant have opposite conductivities.

5. The method of claim 4, wherein the first type dopant is a p-type dopant, and the second type dopant is an n-type dopant.

6. The method of claim 1, wherein the gate spacers and the blocking layer include different material compositions.

7. The method of claim 1, wherein the blocking layer is a first blocking layer and the opening is a first opening, the method further comprising:
depositing a second blocking layer, wherein the first gate structure is positioned between the first and second blocking layers, and the second blocking layer has a second opening; and
forming a strapping well directly under the second opening in the second blocking layer.

8. The method of claim 7, wherein the strapping well and the source/drain structure include dopants of opposite conductivities.

9. The method of claim 1, wherein the forming of the first and second gate structures includes:
etching the frontside surface of the substrate to form a first recess and a second recess, wherein the first recess exposes the first light sensing region, and the second recess exposes the second light sensing region;
depositing a gate dielectric layer and a gate electrode layer in the first recess and the second recess; and
patterning the gate dielectric layer and the gate electrode layer to form the first and second gate structures.

10. The method of claim 9, wherein a bottom surface of the source/drain structure is above bottom surfaces of the first and second gate structures.

11. A method for manufacturing an image sensor structure, comprising:
forming an isolation structure in a substrate to define an enclosure;
forming a light sensing region in the enclosure;
forming a gate structure above the light sensing region;
depositing a first gate spacer on a first sidewall of the gate structure;
depositing a second gate spacer on a second sidewall of the gate structure, the second sidewall being opposing the first sidewall;
depositing a first blocking layer on the first gate spacer, the first blocking layer including a first opening;
depositing a second blocking layer on the second gate spacer, the second blocking layer including a second opening;
implanting a first dopant into the substrate through the first opening to form a first doped region; and
implanting a second dopant into the substrate through the second opening to form a second doped region, the first and second dopants including opposite conductivities.

12. The method of claim 11, further comprising:
depositing a dielectric layer covering the first and second blocking layers, the first and second gate spacers, and the first and second gate structures;
forming a first contact through the dielectric layer and in physical contact with the first doped region; and
forming a second contact through the dielectric layer and in physical contact with the second doped region.

13. The method of claim 12, wherein the first contact is in physical contact with sidewalls of the first opening, and the second contact is in physical contact with sidewalls of the second opening.

14. The method of claim 11, wherein the first dopant is an n-type dopant, and the second dopant is a p-type dopant.

15. The method of claim 11, wherein a size of the first doped region is larger than a size of the second doped region in a top view of the image sensor structure.

16. The method of claim 11, wherein each of the first and second blocking layers has a square shape or a rectangular shape in a top view of the image sensor structure.

17. The method of claim 11, wherein each of the first and second openings is directly above the isolation structure.

18. An image sensor structure, comprising:
an isolation structure in a substate;
first and second light sensing regions at opposite sides of the isolation structure;
first and second gate structures above the first and second light sensing regions, respectively;
gate spacers on sidewalls of the first and second gate structures;
a blocking layer on sidewalls of the gate spacers, wherein the blocking layer has a discontinuity directly above at least a portion of the isolation structure; and
a source/drain structure disposed above the portion of the isolation structure.

19. The image sensor structure of claim 18, wherein the source/drain structure is located directly under the discontinuity of the blocking layer.

20. The image sensor structure of claim 18, wherein a first portion of the blocking layer is directly above the first light sensing region, and a second portion of the blocking layer is directly above the second light sensing region.
